(19) United States
(12) Patent Application Publication
(10) Pub. No.: US 2013/0025538 A1
(43) Pub. Date: Jan. 31, 2013

(54) METHODS AND APPARATUS FOR DEPOSITION PROCESSES

(71) Applicants: RICHARD O. COLLINS, Santa Clara, CA (US); BALASUBRAMANIAN RAMACHANDRAN, Santa Clara, CA (US); ZUOMING ZHU, Sunnyvale, CA (US)

(72) Inventors: RICHARD O. COLLINS, Santa Clara, CA (US); BALASUBRAMANIAN RAMACHANDRAN, Santa Clara, CA (US); ZUOMING ZHU, Sunnyvale, CA (US)

(73) Assignee: APPLIED MATERIALS, INC., Santa Clara, CA (US)

(21) Appl. No.: 13/536,575

(22) Filed: Jun. 28, 2012

Related U.S. Application Data
(60) Provisional application No. 61/512,235, filed on Jul. 27, 2011.

(51) Int. Cl. C30B 25/12; B23Q 3/18; C30B 25/10; C30B 25/08; C30B 25/16

(52) U.S. Cl. 118/712; 269/302

(57) ABSTRACT

Methods and apparatus for processing a substrate are provided herein. In some embodiments, the apparatus may include a ring to support a substrate in a position for processing, wherein the substrate is supported by a top side of the ring proximate a peripheral edge of the substrate such that a backside of the substrate, when present, is disposed over a central opening of the ring, a substantially planar member disposed below the ring, wherein substantially planar member includes plurality of slots, and a plurality of support arms which support the ring and the substantially planar member, wherein each support arm includes a terminal portion that supports the substantially planar member and extends through a respective one of the plurality of slots to support the ring

### CROSS-REFERENCE TO RELATED APPLICATIONS

This application claims benefit of U.S. provisional patent application Ser. No. 61/512,235, filed Jul. 27, 2011, which is herein incorporated by reference.

### FIELD

Embodiments of the present invention generally relate to processing equipment and methods of using the same.

### BACKGROUND

Some selective epitaxial deposition processes that use alternating deposition and etch steps are carried out at substantially different pressures. For example, the deposition process may be carried out at a pressure of about 10 Torr and the etch process may be carried out at a pressure of about 300 Torr. The pressure differential requires repeated changing of the chamber pressure, which undesirably slows process throughput. In addition, the inventors have observed that in certain systems, the pressure must be changed slowly to avoid movement of the substrate due to pressure differences that may develop between the frontside and backside of the substrate. Unfortunately, the slow change of the pressure between deposition and etch processes further slows process throughput. To solve this problem, the substrate support may be configured with a central opening and support ledge to support the substrate being processed proximate an outer edge of the substrate. However, the inventors have observed that such a configuration may result in variable backside emissivity of the substrate, which, in turn, causes inconsistent temperature measurements of the substrate. Such inconsistent temperature measurements result in poor process control which slows process throughput and may reduce process yield.

Accordingly, the inventors have provided improved methods and apparatus for processing substrates.

### SUMMARY

Methods and apparatus for processing a substrate are provided herein. In some embodiments, the apparatus may include a ring to support a substrate in a position for processing, wherein the substrate is supported by a top side of the ring proximate a peripheral edge of the substrate such that a backside of the substrate, when present, is disposed over a central opening of the ring, a substantially planar member disposed below the ring, wherein substantially planar member includes plurality of slots, and a plurality of support arms which support the ring and the substantially planar member, wherein each support arm includes a terminal portion that supports the substantially planar member and extends through a respective one of the plurality of slots to support the ring.

In some embodiments, an apparatus for processing a substrate may include a process chamber, a ring to support a substrate in a position for processing in the process chamber, a substantially planar member disposed in the process chamber and on a first side of the ring, wherein substantially planar member includes a plurality of slots, a plurality of support arms which support the ring and the substantially planar member, wherein each support arm includes a terminal portion that supports the substantially planar member and extends through a respective one of the plurality of slots to support the ring, heat lamps to provide heat to components disposed within the process chamber, wherein the heat lamps are disposed at least one of above the substantially planar member or below the substantially planar member, and a pyrometer to measure temperatures of the components disposed within the process chamber, wherein the pyrometer is disposed below the substantially planar member.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic side view of a process chamber in accordance with some embodiments of the present invention.

FIGS. 2A-2C respectively depict schematic top isometric, side, and bottom isometric views of a substrate support in accordance with some embodiments of the present invention.

FIGS. 3A-3B depict top views of a portion of a substrate support in accordance with some embodiments of the present invention.

FIG. 4 depicts a cross-sectional view of a portion of a substrate support in accordance with some embodiments of the present invention.

FIG. 5 depicts a flow chart for a method of processing a substrate in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

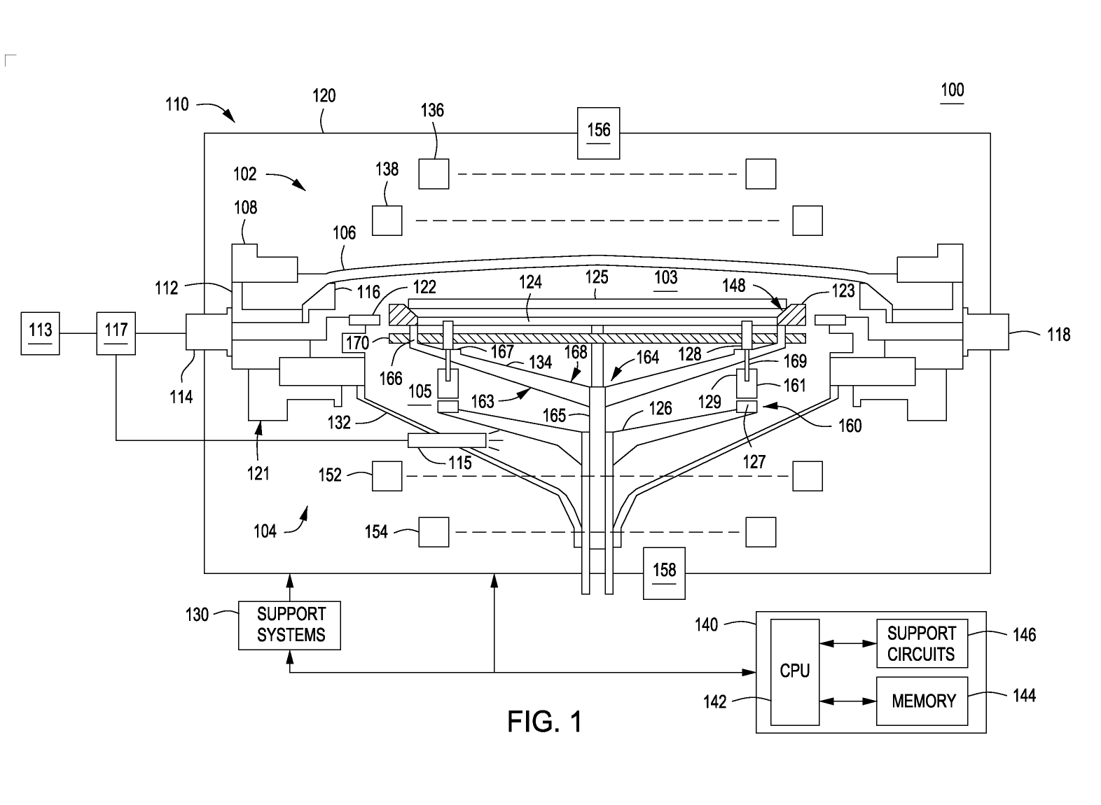

Methods and apparatus for processing substrates are disclosed herein. FIG. 1 depicts a schematic side view of a process chamber 100 in accordance with some embodiments of the present invention. The process chamber 100 may be modified from a commercially available process chamber, such as the RP EPI® reactor, available from Applied Materials, Inc. of Santa Clara, Calif., or any suitable semiconductor process chamber adapted for performing epitaxial deposition processes. Alternatively, the process chamber 100 may be adapted for performing at least one of deposition processes, etch processes, plasma enhanced deposition and/or etch processes, and thermal processes, among other processes performed in the manufacture of integrated semiconductor devices and circuits. Specifically, such processes may include, but are not limited to, processes where rapid pressure changes are utilized during processing.

In some embodiments, the process chamber 100 may be adapted for performing epitaxial deposition processes, and illustratively comprises a chamber body 110, support systems 130, and a controller 140. The chamber body 110 generally includes an upper portion 102 having a first inner volume 103, a lower portion 104 having a second inner volume 105, and an enclosure 120.

The upper portion 102 is disposed on the lower portion 104 and may include a lid 106, a clamp ring 108, a liner 116, a baseplate 112, one or more upper lamps 136 and one or more lower lamps 138, and an upper pyrometer 156. In one embodiment, the lid 106 has a dome-like form factor, however, lids having other form factors (e.g., flat or reverse-curve lids) are also contemplated. The lower portion 104 is coupled to a first gas inlet port 114 and an exhaust port 118 and comprises a baseplate assembly 121, a lower dome 132, a substrate support 124, a pre-heat ring 122, one or more upper lamps 152, one or more lower lamps 154, and a lower pyrometer 158. Although the term “ring” or “disc” is used to describe certain components of the process chamber, such as the pre-heat ring 122, it is contemplated that the shape of these components need not be circular and may have a perimeter and/or opening of any shape, including but not limited to, rectangles, polygons, ovals, and the like.

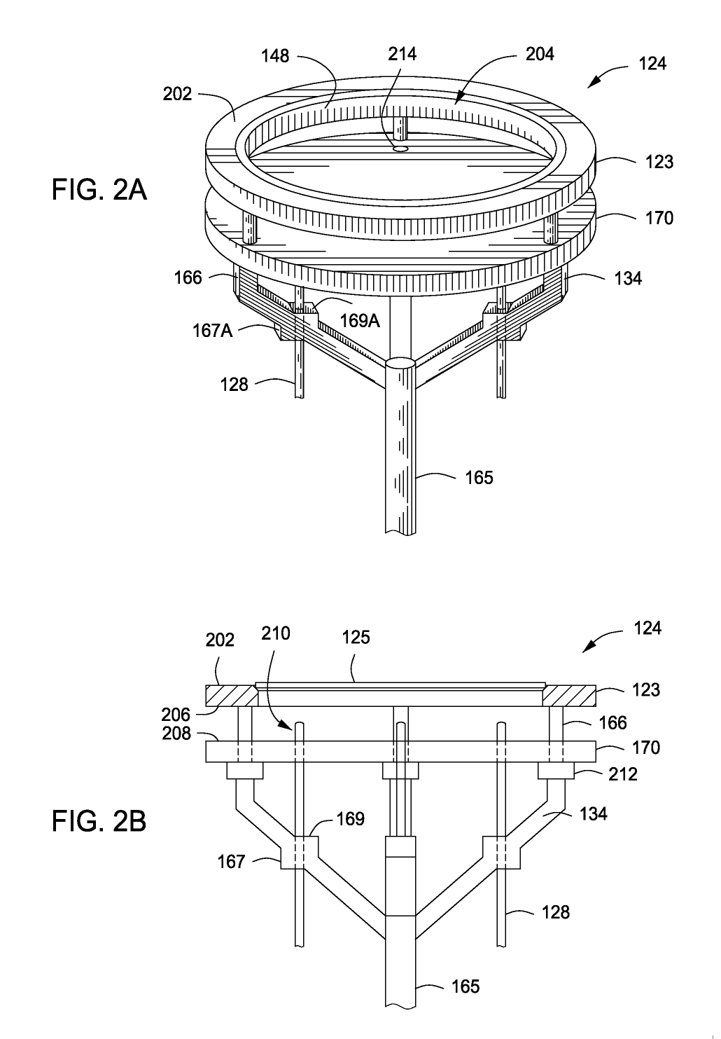

In some embodiments, the substrate support 124 generally includes a ring 123, a substantially planar member 170, a substrate support assembly 164 for supporting each of the ring 123 and the substantially planar member 170 in a desired position, and a substrate lift assembly 160. In addition to the description with respect to FIG. 1, FIGS. 2A-2C respectively depict schematic top isometric, side, and bottom isometric views of a substrate support in accordance with some embodiments of the present invention and generally show the relation between the ring 123 and the substantially planar member 170.

The ring 123 supports a substrate 125 on a first side thereof. In some embodiments, the ring 123 may include a feature 148, such as a ledge, a chamfer, a protrusion, or other suitable feature, to support the substrate 125 on the ring 123 such that the substrate 125 is disposed over the central opening of the ring 123. In some embodiments, the feature may be disposed along an inner peripheral edge of the ring 123 on a first side of the ring 123. In some embodiments, a backside of the substrate 125 (e.g., the side opposite the frontside of the substrate that is to be processed) may be aligned with a central opening of the ring 123. The ring 123 may comprise at least one of silicon carbide coated graphite, solid silicon carbide, solid sintered silicon carbon, or solid metal-free sintered silicon carbide.

The substantially planar member 170 is disposed on a side of the ring 123 opposite the substrate 125, such that the substantially planar member 170 faces the backside of the substrate 125. In some embodiments, the substantially planar member 170 is opaque to infrared light. In other embodiments, the substantially planar member 170 may be partially, substantially, or completely transparent to infrared light such that the amount of heat absorbed by the substantially planar member 170 may be controlled by the level of transparency of the substantially planar member 170. In some embodiments, the substantially planar member 170 comprises at least one of silicon carbide coated graphite, solid silicon carbide, solid sintered silicon carbon, or solid metal-free sintered silicon carbide. In some embodiments, the substantially planar member 170 and the ring 123 are comprise the same material.

In some embodiments, the substantially planar member 170 has a primary surface that is larger than the diameter or width of the substrate 125. Providing a primary surface that is larger than the substrate 125 advantageously provides a more uniform envelope of processing equipment about the substrate 125, thereby facilitating more uniform processing. For example, the inventors have discovered that when heating a substrate disposed on a support ring from the top and bottom of a process chamber, the use of regular emissivity compensation mechanisms such as black body cavity techniques or the like, is impeded and process temperatures may be incorrectly measured, leading to poor process control and poor quality. The inventors have discovered that the use of the substantially planar member 170 advantageously limits the effects of variation in substrate backside emissivity by providing a constant emissivity regardless of the substrate 125 used in the process chamber 100. The substantially planar member 170 provides a surface with a substantially constant emissivity, providing a more constant temperature reading to, for example, the lower pyrometer 158, thereby facilitating improved process control. Furthermore, the substantially planar member 170 provides a significant thermal mass that advantageously radiates heat within the process chamber 100. This may advantageously reduce thermal shock to the substrate during substrate removal after processing and may further advantageously enhance chamber cleaning processes by enabling higher processing temperatures. The use of a substrate support as described herein further may advantageously facilitate ultra low temperature epitaxial deposition with stable thermal control by balancing direct top heating, for example using lamps, and bottom susceptor emissive heating using the substantially planar member 170.

The substantially planar member 170 is disposed in a spaced apart relation to the ring 123 on a side opposite the substrate 125. The substantially planar member 170 may be spaced apart from the ring 123, and therefore, the substrate 125 when present, by any suitable distance. For example, the substantially planar member 170 may be separated from the ring 123 at a distance selected to allow for the backside emissivity independence and/or the enhanced chamber clean performance discussed above. In some embodiments, the substantially planar member 170 is spaced from about 0.1 to about 0.3 inches apart from the ring 123.

For example, in some embodiments, the ring 123 may be supported by a plurality of support pins 166. The support pins 166 may be in turn, supported by respective support arms 134 of the substrate support assembly 164. In some embodiments, the substantially planar member 170 may include respective openings to allow the support pins 166 to pass through the substantially planar member 170. The substantially planar member 170 may be supported, directly or indirectly, by the support arms 134 such that the length of the support pins 166 and the thickness of the substantially planar member 170 may define the space between the substantially planar member 170 and the ring 123. Alternatively, support pins may be disposed atop the substantially planar member 170.

As better shown in FIGS. 2A-B, the ring 123 may have a first side 202 for supporting the substrate 125 across a central opening 204 of the ring 123. The substantially planar member 170 is spaced apart from the ring 123 and has a primary surface 208 facing a second side 206 of the ring 123. In some embodiments, the primary surface 208 together with the second side 206 of the ring 123 define a substantially uniform gap 210.

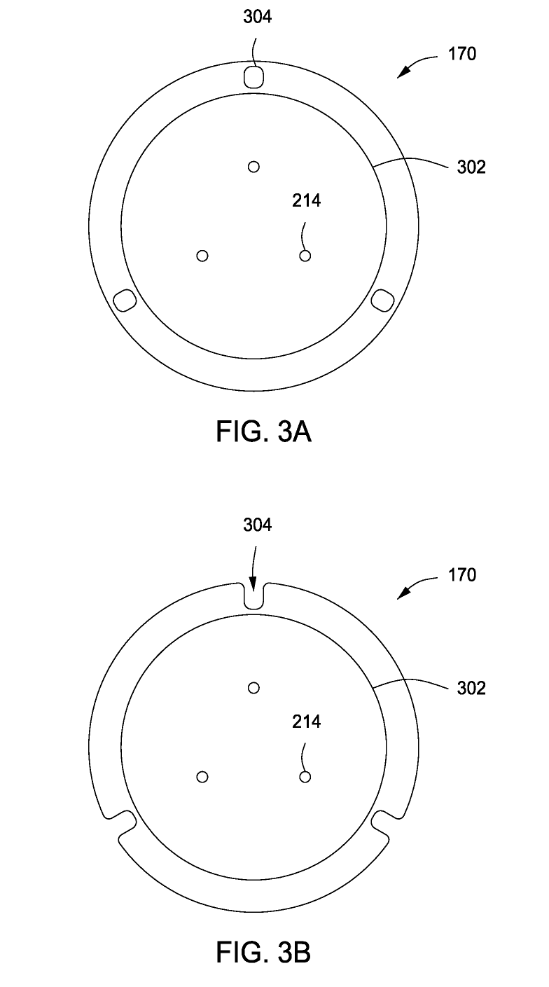

In some embodiments, the distance between the substantially planar member 170 and the ring 123 (e.g., the size of the gap 210) may be controlled. For example, as shown in FIGS. 1 and 2B the length of the support pins 166 may control the size of the gap 210 (in combination with the thickness of the substantially planar member 170). In some embodiments, and as depicted in FIGS. 2B and 4, one or more spacers 212 may be provided to facilitate controlling the distance between the substantially planar member 170 and the ring 123, for example, for different processes. In some embodiments, the spacers 212 may have a thickness of about 0.1, about 0.2, and/or about 0.3 inches. Use of spacers 212 facilitates more rapid changeover of the process equipment for different processes, thereby reducing equipment downtime. As also depicted in FIG. 4, a feature 402 may be provided in the ring 123 to facilitate locating and retaining the ring 123 in a desired position atop the support pins 166. For example, as shown in FIG. 4, the feature 402 is a recess disposed in the second side 206 of the ring 123.

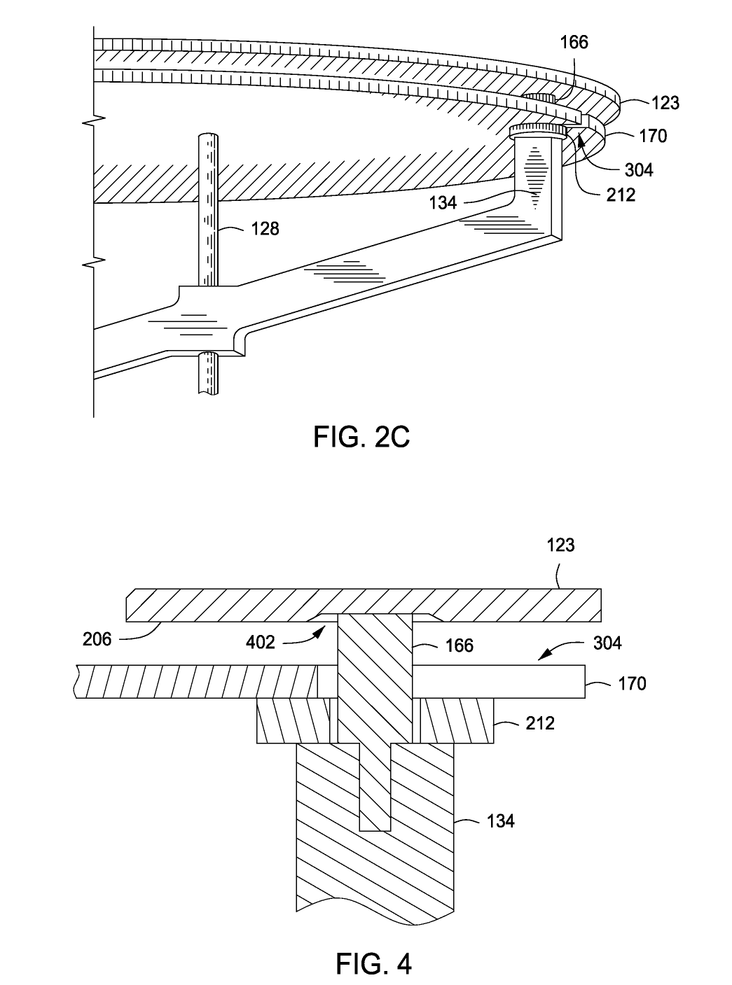

In some embodiments, the substantially planar member 170 has a substantially uniform thickness and has no features or openings in the substantially planar member 170 other than a plurality of lift pin openings and a plurality of openings to interface with the supporting member 163 of the substrate support assembly 164. For example, in some embodiments, and as depicted in FIGS. 3A-3B, the substantially planar member 170 is in the shape of a circular disc with a diameter greater than that of a substrate 125 to be processed, such as in the range of 300 mm to 600 mm. In some embodiments, the substantially planar member 170 may have a thickness suitable to provide a desired thermal mass of the substantially planar member 170. For example, in some embodiments, the substantially planar member 170 may have a thickness of about 3 mm to about 7 mm In some embodiments, the substantially planar member 170 may have a circular groove 302 formed in a substrate facing surface of the substantially planar member 170. The circular groove 302 facilitates providing an escape path for gases when the substantially planar member 170 touches or is close to touching the ring 123 to prevent gas trapping. The substantially planar member 170 contains a plurality of lift pin holes 214 to allow the respective lift pins 128 to move through the lift pin holes 214, for example, to raise or lower the substrate. In some embodiments, the lift pin holes may be disposed at a suitable distance from the center of the substantially planar member 170 and may be azimuthally evenly spaced apart, e.g., spaced 120 degrees apart. The addition of the substantially planar member 170 has further been found to provide additional support for the lift pins 128 due to the additional support provided by the substantially planar member 170.

In some embodiments, the substantially planar member 170 includes slots 304 to allow the support pins 166 to pass though the substantially planar member 170 and to locate and retain the substantially planar member 170 in place on the substrate support assembly 164. The slots 304 may be disposed completely within, but proximate an edge of the substantially planar member 170 (as shown in FIG. 3A) or may extend in from the edge of the substantially planar member 170 (as shown in FIG. 3B). The slots 304 may have a dimension that is larger than the diameter of the support pins 166 to facilitate changes in size and/or relative position due to thermal expansion and contraction. In some embodiments the slots 304 may have a major axis that is radially aligned with a central axis of the substrate support assembly 164. In some embodiments, the slots 304 may be radially aligned with respective lift pin holes 214 to facilitate providing the lift pins and the support for the substantially planar member 170 and the ring 123 along the same supporting members 163 of the substrate support assembly 164.

Returning to FIG. 1, the substrate support assembly 164 generally includes a central support 165 having a supporting member 163 radially extending therefrom for supporting the ring 123 and substantially planar member 170 on the supporting member 163. Each supporting member 163 includes a respective lift pin supporting surface 167 on a ring-facing side 168 of the supporting member 163. Each lift pin supporting surface 167 has a lift pin hole 169 disposed therethrough between the ring-facing side 168 and a backside of the supporting member 163. Each lift pin hole 169 may be configured to have a lift pin 128 moveably disposed therethrough. Each lift pin supporting surface 167 may be configured to support a lift pin 128 when the lift pin is in a retracted position.

In some embodiments, the supporting member 163 further comprises a plurality of support arms 134. Each support arm 134 may have a respective one lift pin supporting surface 167 disposed thereon and a lift pin hole 169 disposed therethrough. In some embodiments, each support arm 134 may further include a support pin 166 for coupling the support arm to the substantially planar member 170. In some embodiments, the number of support arms 134, the number of lift pins 128, and the number of support pins 166 is three.

Alternatively, and not shown, the supporting member 163 may be a single-piece conical member. The conical member may further include a plurality of vents disposed therethrough for fluidly coupling the backside of the substrate 125 to the second inner volume 105 of the process chamber 100. In such embodiments, the conical member may be absorptive or transmissive of radiant energy provided during processing, to control the temperature of the substrate as desired.

The substrate lift assembly 160 may be disposed about the central support 165 and axially moveable therealong. The substrate lift assembly 160 comprises a substrate lift shaft 126 and a plurality of lift pin modules 161 selectively resting on respective pads 127 of the substrate lift shaft 126. In some embodiments, a lift pin module 161 comprises an optional base 129 and a lift pin 128 coupled to the base 129. Alternatively, a bottom portion of the lift pin 128 may rest directly on the pads 127. In addition, other mechanisms for raising and lowering the lift pins 128 may be utilized.

Each lift pin 128 is movably disposed through the lift pin hole 169 in each support arm 134 and can rest on the lift pin supporting surface 167 when the lift pin 128 is in a retracted position, for example, such as when the substrate 125 has been lowered onto the ring 123. In operation, the substrate lift shaft 126 is moved to engage the lift pins 128. When engaged, the lift pins 128 may raise the substrate 125 above the substrate support 124 or lower the substrate 125 onto the ring 123.

The lamps 136, 138, 152, and 154 are sources of infrared (IR) radiation (i.e., heat) and, in operation, generate a pre-determined temperature distribution across the substrate 125. In some embodiments, the lid 106, the clamp ring 116, and the lower dome 132 are formed from quartz; however, other IR-transparent and process compatible materials may also be used to form these components.

The process chamber 100 further includes a gas panel 113 for supplying process gases to first and second inner volumes 103, 105 of the process chamber 100. For example, the gas panel 113 may provide process gases, such as deposition gases, etchants, or the like, and/or other gases such as carrier gases, gases for dilution, gases for chamber pressurization, or the like. The gas panel 113 provides gases to the first gas inlet port 114 and a second gas inlet port 115 coupled to the process chamber 100 at the lower dome 132. The coupling point of the second gas inlet port 115 (e.g., at the lower dome 132) is merely exemplary, and any suitable coupling point which allows the second gas inlet port 115 to provide gases to the second inner volume 105 may be used.

Generally, the first gas inlet port 114 provides a process gas to the first inner volume 103 to process the substrate 125 disposed on any of the embodiments of a substrate support 124 discussed above. The second gas inlet port 115 provides a pressurizing gas to the second inner volume 105 to facilitate raising the chamber pressure to a desired chamber pressure at a desired pressure ramping rate. In some embodiments, the desired chamber pressure ranges from about 30 to about 600 Torr. In some embodiments, the desired pressure ramping rate ranges from about 30 to about 150 Torr/sec.

In some embodiments, when increasing the chamber pressure during the etch portion of a selective epitaxial deposition process, a process gas including an etchant gas can be flowed into the first inner volume 103 via the first gas inlet port 114. Simultaneously, a pressurizing gas may be flowed into the second inner volume 105 via the second gas inlet port 115 to facilitate raising the chamber pressure to the desired pressure for the etch portion of the selective deposition process.

In some embodiments, the process chamber 100 includes a pressure control valve 117 coupled between the gas panel 113 for supplying the process and pressurizing gases and the first and second gas inlet ports 114, 115. The pressure control valve may regulate the flow of the process and pressurizing gases such that the chamber pressure does not substantially exceed the desired chamber pressure during ramping the pressure at the desired pressure ramping rate (e.g., the chamber pressure does not exceed the desired chamber pressure by more than about 10%, or by about 3% to about 5%).

The support systems 130 include components used to execute and monitor pre-determined processes (e.g., growing epitaxial silicon films) in the process chamber 100. Such components generally include various sub-systems (e.g., gas panel(s), gas distribution conduits, vacuum and exhaust sub-systems, and the like) and devices (e.g., power supplies, process control instruments, and the like) of the process chamber 100. These components are well known to those skilled in the art and are omitted from the drawings for clarity.

The controller 140 generally comprises a central processing unit (CPU) 142, a memory 144, and support circuits 146 and is coupled to and controls the process chamber 100 and support systems 130, directly (as shown in FIG. 1) or, alternatively, via computers (or controllers) associated with the process chamber 100 and/or the support systems. The memory 144, or computer readable medium, may contain instructions stored thereon that when executed by the CPU 142, cause the process chamber 100 to perform processing methods, such that the method 500 disclosed below.

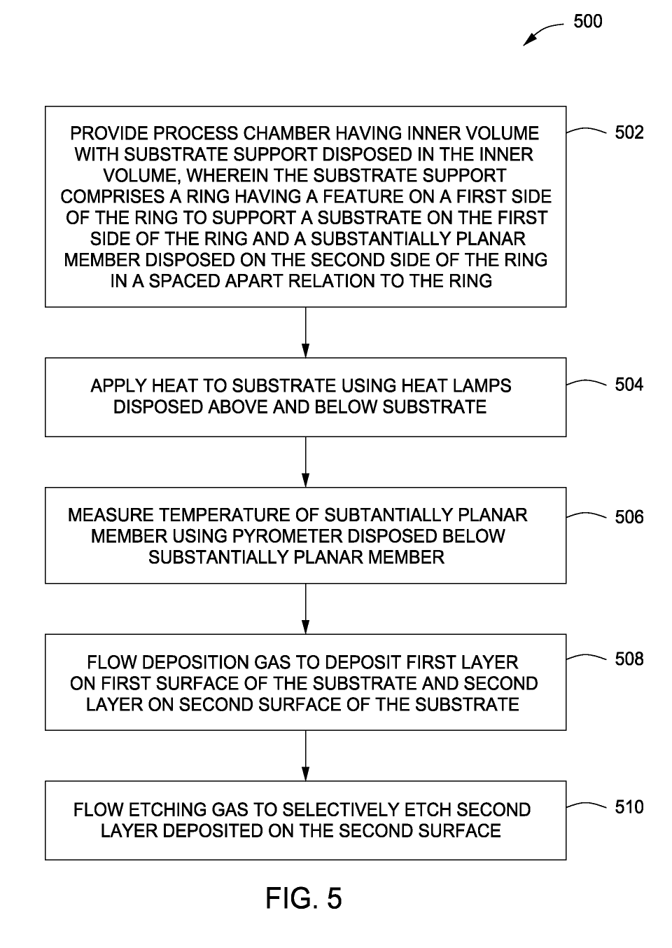

FIG. 5 depicts a flow chart for a method 500 of processing a substrate in accordance with some embodiments of the present invention. The inventive method may be utilized with any of the embodiments of the process chamber 100 and the substrate support 124 discussed above.

The method 500 begins at 502 by providing a process chamber 100 having an inner volume with a substrate support disposed in the inner volume, wherein the substrate support comprises a ring having a feature on a first side of the ring to support a substrate on the first side of the ring and a substantially planar member disposed on the second side of the ring in a spaced apart relation to the ring.

The substrate has a first surface for depositing a first layer thereon and an opposing second surface. The substrate may comprise a suitable material such as crystalline silicon (e.g., Si<100>or Si<111>), silicon oxide, strained silicon, silicon germanium, doped or undoped polysilicon, doped or undoped silicon wafers, patterned or non-patterned wafers, silicon on insulator (SOI), carbon doped silicon oxides, silicon nitride, doped silicon, germanium, gallium arsenide, glass, sapphire, or the like. Further, the substrate may comprise multiple layers, or include, for example, partially fabricated devices such as transistors, flash memory devices, and the like.

At 504, the substrate is heated using heat lamps disposed above and below the substrate as depicted in FIG. 1. At 506, a pyrometer may be used to measure the temperature of the substantially planar member. The pyrometer may be disposed beneath the substantially planar member. The substantially planar member provides a more uniform emissivity to reduce or eliminate the variation in of substrate backside emissivity, thereby providing a more uniform temperature measurement by the pyrometer.

The substrate may be processed in any suitable manner and may use the temperature measurement to confirm or adjust the desired processing temperature of the substrate. For example, at 508, a deposition gas may be flowed to deposit a first layer on the first surface of the substrate at a first chamber pressure. In some embodiments, for example to deposit a silicon-containing film on the substrate, the first chamber pressure ranges from about 0.1 to about 100 Torr. In some embodiments, the deposition gas comprises at least one of silane (SiH₄), disilane (Si₂H₆), methylsilane (H₃CSiH₃) or the like. In some embodiments, the first layer comprises silicon and carbon. In some embodiments, during the deposition process at 404, a second layer may be formed on the second surface. The second layer may be similar in chemical composition to the first layer, but different in chemical structure. For example, the second layer may be non-crystalline, poly-crystalline, amorphous, or any suitable crystalline or non-crystalline structure that differs from the first layer.

In some embodiments, at 510, an etching gas may be flowed into the process chamber to selectively etch the second layer deposited on the second surface. In some embodiments, the etching gas comprises at least one of hydrogen chloride (HCl), chlorine (Cl₂), germane (GeH₄), germanium chloride (GeCl₄), silicon tetrachloride (SiCl₄), carbon tetrachloride (CCL₄), or the like. A pressurizing gas is flowed into the process chamber, simultaneously with flowing the etching gas, to raise the chamber pressure to a second chamber pressure greater than the first chamber pressure at a desired pressure ramping rate. In some embodiments, the pressurizing gas comprises at least one of nitrogen (N₂), hydrogen (H₂), argon (Ar), helium (He), or the like. In some embodiments, the second chamber pressure ranges from about 30 to about 600 Torr. In some embodiment, the desired pressure ramping rate ranges from about 30 to about 150 Torr/sec. The etch process typically occurs at the second pressure. The above described apparatus may also be suitably used in connection with other substrate processes.

Thus, methods and apparatus for processing a substrate have been disclosed herein. While the foregoing is directed to embodiments of the present invention, other and further embodiments of the invention may be devised without departing from the scope thereof.

1. An apparatus for processing a substrate comprising:
a ring to support a substrate in a position for processing, wherein the substrate is supported by a top side of the ring proximate a peripheral edge of the substrate such that a backside of the substrate, when present, is disposed over a central opening of the ring;
a substantially planar member disposed below the ring, wherein substantially planar member includes plurality of slots; and
a plurality of support arms which support the ring and the substantially planar member, wherein each support arm includes a terminal portion that supports the substantially planar member and extends through a respective one of the plurality of slots to support the ring.

2. The apparatus of claim 1, wherein the substantially planar member and the ring are supported by the plurality of supports arms such that a substantially uniform gap region is defined between the top surface of the substantially planar member and a bottom side of the ring.

3. The apparatus of claim 1 wherein the terminal portion of each support arm that supports the substantially planar member and the ring includes (a) a support pin disposed through one of the plurality of slots of the substantially planar member such that the bottom side of the ring rests on the support pin, and (b) a spacer disposed between the substantially planar member and the support arm to support the substantially planar member such that a bottom surface of the substantially planar member rests on the spacer.

4. The apparatus of claim 3, wherein the support pin and the spacer are each sized to position the ring at a selected distance above the substantially planer member.

5. The apparatus of claim 4, wherein the selected distance limits effects of variations in substrate backside emissivity and enhances chamber cleaning processes.

6. The apparatus of claim 4, wherein the support pin and spacer is replaceable with a different sized support pin and spacer to position the ring at a different selected distance above the substantially planer member.

7. The apparatus of claim 3, wherein the support pin and the spacer are integrally formed.

8. The apparatus of claim 3, wherein the support pin and the spacer are removably coupled to each other.

9. The apparatus of claim 3, wherein the spacer is disposed about the support pin and sized to support the substantially planar member in a selected distance with respect to the ring.

10. The apparatus of claim 1, wherein the plurality of support arms are coupled to a central support, wherein each of the plurality of support arms further includes a lift pin supporting surface having a hole disposed through each lift pin supporting surface, and wherein the apparatus further comprises:
a plurality of lift pins, each lift pin moveably disposed through the hole in each lift pin supporting surface and supported by the lift pin supporting surface when the lift pin is in a retracted position.

11. The apparatus of claim 10, wherein the substantially planar member further comprises a plurality of lift pin holes, wherein each of the plurality of lift pins is movably disposed through one the of the lift pin holes in substantially planar member to raise or lower the substrate when present.

12. The apparatus of claim 1, further comprising:
a circular groove formed in the top surface of the substantially planar member, the circular groove having a diameter that is less than a diameter of the central opening of the ring.

13. The apparatus of claim 1, wherein the substantially planar member is opaque to infrared light.

14. The apparatus of claim 1, wherein the substantially planar member is one of (a) partially transparent to infrared light or (b) transparent to infrared light.

15. The apparatus of claim 1, wherein a top surface of the substantially planar member has a substantially constant emissivity.

16. The apparatus of claim 2, wherein the plurality of supports arms position the ring between 0.1 to 0.3 inches above the substantially planer member.

17. The apparatus of claim 1, the substantially planar member and the ring each comprise a metal-free sintered silicon carbide.

18. An apparatus for processing a substrate comprising
a process chamber;
a ring to support a substrate in a position for processing in the process chamber;
a substantially planar member disposed in the process chamber and on a first side of the ring, wherein substantially planar member includes a plurality of slots;
a plurality of support arms which support the ring and the substantially planar member, wherein each support arm includes a terminal portion that supports the substantially planar member and extends through a respective one of the plurality of slots to support the ring;
heat lamps to provide heat to components disposed within the process chamber, wherein the heat lamps are disposed at least one of above the substantially planar member or below the substantially planar member; and
a pyrometer to measure temperatures of the components disposed within the process chamber, wherein the pyrometer is disposed below the substantially planar member.

19. The apparatus of claim 18, wherein the substantially planar member and the ring are supported by the plurality of supports arms such that a substantially uniform gap region is defined between the top surface of the substantially planar member and a bottom side of the ring.

20. The apparatus of claim 18 wherein the terminal portion of each support arm that supports the substantially planar member and the ring includes (a) a support pin disposed through one of the plurality of slots of the substantially planar member such that the bottom side of the ring rests on the support pin, and (b) a spacer disposed between the substantially planar member and the support arm to support the substantially planar member such that a bottom surface of the substantially planar member rests on the spacer.
